(19) United States
(12) Patent Application Publication
(10) Pub. No.: US 2016/0272854 A1
(43) Pub. Date: Sep. 22, 2016

(54) ADHESIVE FOR MOUNTING ELECTRONIC COMPONENT AND ADHESIVE FILM FOR MOUNTING FLIP CHIP

(71) Applicant: SEKISUI CHEMICAL CO., LTD., Osaka (JP)

(72) Inventor: Sayaka WAKIOKA, Osaka (JP)

(73) Assignee: SEKISUI CHEMICAL CO., LTD., Osaka (JP)

(21) Appl. No.: 15/035,336

(22) PCT Filed: Feb. 27, 2015
(86) PCT No.: PCT/JP2015/055764

§ 371 Date: May 9, 2016

(30) Foreign Application Priority Data
Mar. 4, 2014 (JP) 2014-042064

(51) Int. Cl. C09J 133/06; H01L 23/00; C09J 163/10; C09J 133/14; C09J 133/08

(52) U.S. Cl. CPC C09J 133/066; C09J 133/14; C09J 133/08; C09J 163/10; H01L 24/32; C09J 2203/326; H01L 2224/32501; H01L 2224/32258; H01L 2224/32148; H01L 2224/2969

(57) ABSTRACT

The present invention aims to provide an adhesive for mounting an electronic component. The adhesive enables sufficient soldering while preventing solder flow in a short mounting time, suppresses voids, and is excellent in reflowing resistance. The present invention also aims to provide an adhesive film for mounting a flip chip including the adhesive for mounting an electronic component. The present invention relates to an adhesive for mounting an electronic component including: an acrylic polymer having a (meth)acryloyl group in a side chain and having a double bond equivalent of 1 to 5 meq/g; a tri- or higher functional (meth)acrylate compound; and a radical polymerization initiator.

### TECHNICAL FIELD

The present invention relates to an adhesive for mounting an electronic component. The adhesive enables sufficient soldering while preventing solder flow in a short mounting time, suppresses voids, and is excellent in reflowing resistance. The present invention also relates to an adhesive film for mounting a flip chip. The adhesive film contains the adhesive for mounting an electronic component.

### BACKGROUND ART

Along with the recent development of smaller and higher-integration semiconductor devices, attention has been paid to flip chip mounting in which a semiconductor chip with a bump electrode (bump) made of solder or the like is used.

In the flip chip mounting, commonly, a bump electrode of a semiconductor chip is bonded to an electrode of another semiconductor chip or a substrate, and an underfill resin is injected to achieve sealing with resin (see Patent Literature 1).

Along with recent downsizing of semiconductor chips, the pitch between electrodes has become narrower. In addition, the gap between semiconductor chips or between a semiconductor chip and a substrate also becomes narrower. Accordingly, air is likely to be caught upon injection of an underfill resin, which tends to form voids.

In a method employed to solve such a problem, an underfill resin is not injected after bonding of electrodes but a substrate or a semiconductor chip is preliminarily provided with a thermosetting adhesive or adhesive film. With this structure, bonding of electrodes and curing of the adhesive can be concurrently performed by heating, so that a semiconductor chip is mounted (see Patent Literature 2).

In this method, however, if the adhesive is cured slowly, the adhesive may be insufficiently cured when solder is molten and the molten solder may flow due to the fluidity of the adhesive (solder flow). Moreover, if the adhesive is not sufficiently cured at the time of the mounting, voids tend to be formed in the cooling step after the mounting. Though the mounting time in the flip chip mounting is required to be short for good productivity, conventional adhesives or adhesive films hardly achieve sufficient soldering while preventing solder flow in a short mounting time.

### CITATION LIST

### Patent Literature

Patent Literature 1: JP 2010-278334 A
Patent Literature 2: JP 2011-29392 A

### SUMMARY OF INVENTION

### Technical Problem

The present invention aims to provide an adhesive for mounting an electronic component. The adhesive enables sufficient soldering while preventing solder flow in a short mounting time, suppresses voids, and has excellent reflowing resistance. The present invention also′aims to provide an adhesive film for mounting a flip chip. The adhesive film contains the adhesive for mounting an electronic component.

### Solution to Problem

The present invention relates to an adhesive for mounting an electronic component including: an acrylic polymer having a (meth)acryloyl group in a side chain and having a double bond equivalent of 1 to 5 meq/g; a tri- or higher functional (meth)acrylate compound; and a radical polymerization initiator.

The present invention is specifically described in the following.

With an aim of achieving sufficient soldering while preventing solder flow in a short mounting time, the present inventor made a study on an adhesive for mounting an electronic component which contains an acrylic polymer that has a (meth)acryloyl group in a side chain and is cured by a radical polymerization reaction.

For example, an adhesive composition containing an acrylic polymer (JP 2010-126617 A), a resin composition containing a compound that is a polymer or a copolymer of a diene compound and has polymerizable carbon-carbon double bonds at both terminals (JP 5228419 B) are conventionally known. These compositions, however, aim to maintain the bonding reliability (e.g., heat resistance, wet-heat stability) after bonding of electronic components, and are difficult to achieve sufficient soldering while preventing solder flow in a short mounting time in the flip chip mounting.

To overcome the above problem, the present inventor obtained the following new finding: when an adhesive for mounting an electronic component contains an acrylic polymer having a (meth)acryloyl group in a side chain and having a double bond equivalent of 1 to 5 meq/g, a tri- or higher functional (meth)acrylate compound, and a radical polymerization initiator, the adhesive enables sufficient soldering while preventing solder flow in a short mounting time, suppresses voids, and has excellent reflowing resistance. In this manner, the present invention was completed.

The adhesive for mounting an electronic component of the present invention includes: an acrylic polymer having a (meth)acryloyl group in a side chain and having a double bond equivalent of 1 to 5 meq/g (hereafter, also simply referred to as a “acrylic polymer having a (meth)acryloyl group in a side chain”); a tri- or higher functional (meth)acrylate compound; and a radical polymerization initiator.

Containing these components, the adhesive for mounting an electronic component of the present invention is cured by a radical polymerization reaction and can achieve sufficient soldering while preventing solder flow in a short mounting time. In addition, the adhesive is sufficiently cured upon the mounting and suppresses formation of voids in the cooling step after the mounting. Moreover, the adhesive for mounting an electronic component of the present invention is excellent in the bonding reliability and has better reflowing resistance.

The acrylic polymer having a (meth)acryloyl group in a side chain is not particularly limited as long as it has a (meth)acryloyl group in a side chain. Preferably, it has a (meth)acryloyl group only in a side chain.

The phrase “has a (meth)acryloyl group in a side chain” means that a (meth)acryloyl group is not present at one or both terminals of the “main chain” that is the longest carbon chain but in a “side chain” branched from the main chain.

The lower limit of the double bond equivalent of the acrylic polymer having a (meth)acryloyl group in a side chain is 1 meq/g, whereas the upper limit thereof is 5 meq/g. If the double bond equivalent is less than 1 meq/g, solder flow tends to occur to lower soldering properties. In addition, voids tend to be formed in the cooling step after the mounting. An acrylic polymer having a (meth)acryloyl group in a side chain and having a double bond equivalent of more than 5 meq/g is hardly synthesized as it tends to be gelled upon polymerization or a reaction in synthesis thereof. The lower limit of the double bond equivalent is preferably 1.1 meq/g, and the upper limit thereof is preferably 4.5 meq/g. The lower limit is more preferably 1.2 meq/g, and the upper limit is more preferably 4 meq/g.

The double bond equivalent as used herein refers to an index of the average number of (meth)acryloyl groups per gram of the acrylic polymer having a (meth)acryloyl group in a side chain, and is specifically calculated using the following formula (a):

Double bond equivalent (meq/g)=[Average number of (meth)acryloyl groups per molecule of acrylic polymer having (meth)acryloyl group in side chain]×1000/[Number average molecular weight of acrylic polymer having (meth)acryloyl group in side chain] (a).

The double bond equivalent can be calculated by determining the iodine number.

The acrylic polymer having a (meth)acryloyl group in a side chain is preferably obtained by reacting a functional group-containing acrylic polymer with a compound that is reactive with the functional group of the acrylic polymer and has a (meth)acryloyl group.

It is to be noted that not all functional groups of the functional group-containing acrylic polymer are necessarily reacted with the compound that is reactive with the functional group of the functional group-containing acrylic polymer and has a (meth)acryloyl group.

The functional group-containing acrylic polymer is prepared, for example, by polymerizing or copolymerizing a monomer mixture containing a functional group-containing (meth)acrylic monomer. The polymerization method is not particularly limited, and any conventionally known method may be employed, such as solution polymerization (boiling polymerization or isothermal polymerization), emulsion polymerization, suspension polymerization, or bulk polymerization.

Any functional group-containing (meth)acrylic monomer may be used, and examples thereof include: hydroxy group-containing (meth)acrylic monomers such as 4-hydroxybutyl (meth)acrylate, glycerol mono(meth)acrylate, 1,6-hexanediol (meth)acrylate, hydroxyethyl (meth)acrylate, and polypropylene glycol mono(meth)acrylate; amide group-containing (meth)acrylic monomers such as N-methyl (meth)acrylamide; isocyanate group-containing (meth)acrylic monomers such as (meth)acryloyloxyethyl isocyanate, meta-isopropenyl-α,α-dimethylbenzyl isocyanate, (meth)acryloyl isocyanate, and allyl isocyanate; epoxy group-containing (meth)acrylic monomers such as glycidyl (meth)acrylate; carboxyl group-containing (meth)acrylic monomers such as (meth)acrylic acid; and amino group-containing (meth)acrylic monomers such as aminoethyl (meth)acrylate. These functional group-containing (meth)acrylic monomers may be used alone, or in combination of two or more thereof.

The monomer mixture may contain, in addition to the functional group-containing (meth)acrylic monomer, for example, any of vinyl compounds such as N-vinylpyrrolidone, N-vinylcaprolactam, N-acryloylmorpholine, acrylonitrile, styrene, and vinyl acetate; alkyl(meth)acrylates such as methyl(meth)acrylate, ethyl(meth)acrylate, propyl(meth)acrylate, n-butyl(meth)acrylate, tert-butyl(meth)acrylate, 2-ethylhexyl(meth)acrylate, n-octyl(meth)acrylate, isooctyl(meth)acrylate, isononyl(meth)acrylate, isomyristyl(meth)acrylate, and stearyl(meth)acrylate; cyclohexyl(meth)acrylate, isobornyl(meth)acrylate, benzyl(meth)acrylate, 2-butoxyethyl(meth)acrylate, 2-phenoxyethyl(meth)acrylate, and tetrahydrofurfuryl (meth)acrylate. These monomers maybe used alone, or in combination of two or more thereof.

Examples of the compound that is reactive with the functional group of the functional group-containing acrylic polymer and has a (meth)acryloyl group include compounds that have a functional group, such as a carboxyl group, a hydroxy group, an epoxy group, an amino group, an isocyanate group, and an amide group, and have a (meth)acryloyl group. The following cases (1) to (5) are listed as specific examples.

(1) In the case of a hydroxy group-containing acrylic polymer, it may be reacted with a compound that has at least one selected from the group consisting of an amide group, an isocyanate group, an epoxy group, and a carboxyl group and has a (meth)acryloyl group.

(2) In the case of a carboxyl group-containing acrylic polymer, it may be reacted with a compound that has an epoxy group or an isocyanate group and has a (meth)acryloyl group.

(3) In the case of an epoxy group-containing acrylic polymer, it may be reacted with a compound that has a carboxyl group or an amide group and has a (meth)acryloyl group.

(4) In the case of an amino group-containing acrylic polymer, it may be reacted with a compound that has an epoxy group and has a (meth)acryloyl group.

(5) In the case of an isocyanate group-containing acrylic polymer, it may be reacted with a compound that has a hydroxy group or a carboxyl group and has a (meth)acryloyl group.

The acrylic polymer having a (meth)acryloyl group in a side chain may have any weight average molecular weight (Mw), and the lower limit thereof is preferably 10,000 and the upper limit thereof is preferably 1,000,000. When the weight average molecular weight is less than 10,000, the cured adhesive for mounting an electronic component may be fragile, which is likely to lower the reflowing resistance. When the weight average molecular weight is more than 1,000,000, the viscosity of the adhesive for mounting an electronic component becomes too high, which is likely to lower film-forming properties or cause the resin (adhesive) to be trapped in a soldered part upon the mounting. The lower limit of the weight average molecular weight is more preferably 100,000 and the upper limit thereof is more preferably 800,000.

The weight average molecular weight (Mw) is measured as the molecular weight in terms of polystyrene by the gel permeation chromatography (GPC) method. Specifically, the weight average molecular weight (Mw) is measured as the molecular weight in terms of polystyrene by diluting the acrylic polymer with tetrahydrofuran (THF) by a factor of 50, filtering the resulting diluted solution, and treating the filtrate by the GPC method. The device used in the GPC method may be, for example, 2690 Separations Model (Waters Corporation).

Examples of the tri- or higher functional (meth)acrylate compound include: trifunctional compounds such as ethoxylated isocyanuric acid tri(meth)acrylate, trimethylolethane tri(meth)acrylate, pentaerythritol tri(meth)acrylate, and trimethyrolpropane tri(meth)acrylate; tetrafunctional compounds such as ditrimethylolpropane tetra(meth)acrylate, pentaerythritol tetra(meth)acrylate, and dipentaerythritol tetra(meth)acrylate; pentafunctional compounds such as dipentaerythritol penta(meth)acrylate; hexafunctional compounds such as dipentaerythritol hexa(meth)acrylate; and other tri- or higher functional (meth)acrylate compounds, tri- or higher functional urethane (meth)acrylate compounds, and tri- or higher functional polyester (meth)acrylate compounds. These tri- or higher functional (meth)acrylate compounds may be used alone, or in combination of two or more thereof. Particularly preferred among these is ethoxylated isocyanuric acid tri(meth)acrylate because it highly adheres to a semiconductor wafer or chip made of silicone or the like and does not have detachment or a package crack at the adhesion interface with the semiconductor wafer or chip even under the severe wet heat conditions such as reflowing.

The tri- or higher functional (meth)acrylate compound refers to a compound having three or more (meth)acrylate moieties in one molecule. If the number of (meth)acrylate moieties in one molecule is two or less, solder flow is likely to occur to lower soldering properties and voids are likely to be formed in the cooling step after the mounting. The “tri- or higher functional (meth)acrylate compound” as used herein does not include a compound having an epoxy group in addition to (meth)acrylate moieties in one molecule. Such a compound is included in an “epoxy resin” described later.

The amount of the tri- or higher functional (meth)acrylate compound is not particularly limited, and the lower limit thereof is preferably 20 parts by weight and the upper limit thereof is preferably 300 parts by weight for 100 parts by weight of the acrylic polymer having a (meth)acryloyl group in a side chain. If the amount is less than 20 parts by weight, solder flow is likely to occur to lower soldering properties and voids are likely to be formed in the cooling step after the mounting. If the amount is more than 300 parts by weight, the adhesive for mounting an electronic component has higher tackiness. In such a case, if the adhesive is formed into an adhesive film, a trouble may occur upon peeling of a base material with a mold release agent which is laminated on an adhesive layer for protection before use. Moreover, in the pick-up step in which a divided semiconductor chip with an adhesive layer is picked up and mounted on a substrate or another semiconductor chip, the adhesive layer may adhere to the stage, resulting in a pick-up failure. The lower limit of the amount is more preferably 25 parts by weight, and the upper limit thereof is more preferably 250 parts by weight.

The radical polymerization initiator is not particularly limited, and a polymerization initiator commonly used in radical polymerization may be used. Preferred is a heat radical polymerization initiator. Examples of the heat radical polymerization initiator include azo compounds and peroxides. These heat radical polymerization initiators maybe used alone, or in combination of two or more thereof. In the case of using an azo compound, nitrogen is generated as outgas upon reaction to possibly form voids in the cured product. Accordingly, peroxides are more preferred.

Examples of the azo compounds include 2,2′-azobis(isobutyronitrile), 2,2′-azobis(2-methylbutyronitrile), 2,2′-azobis(2,4-dimethylvaleronitrile), 2,2′-azobis(4-methoxy-2,4-dimethylvaleronitrile), 1,1-azobis(cyclohexane-1-carbonitrile), 1-[(1-cyano-1-methylethyl)azo]formamide, 4,4′-azobis(4-cyanovaleric acid), dimethyl-2,2′-azobis(2-methylpropionate), dimethyl-1,1′-azobis(1-cyclohexane carboxylate), 2,2′-azobis{2-methyl-N-[1,1′-bis(hydroxymethyl)-2-hydroxyethyl]propionamide}, 2,2′-azobis[2-methyl-N-(2-hydroxyethyl)propionamide], 2,2′-azobis[N-(2-propenyl)-2-methylpropionamide], 2,2′-azobis(N-butyl-2-methylpropionamide), 2,2′-azobis(N-cyclohexyl-2-methylpropionamide), 2,2′-azobis[2-(2-imidazolin-2-yl)propane]dihydrochloride, 2,2′-azobis{2-[1-(2-hydroxyethyl)-2-imidazolin-2-yl]propane}dihydrochloride, 2,2′-azobis[2-(2-imidazolin-2-yl)propane], 2,2′-azobis(2-amidinopropane)dihydrochloride, 2,2′-azobis[N-(2-carboxyethyl)-2-methylpropionamidine]tetrahydrate, 2,2′-azobis(1-imino-1-pyrrolidino-2-methylpropane)dihydrochloride, and 2,2′-azobis(2,4,4-trimethylpentane). These azo compounds may be used alone, or in combination of two or more thereof.

The peroxide is not particularly limited, and preferably has a 10-hr half-life temperature of 80° C. or higher but lower than 140° C. If the 10-hr half-life temperature is lower than 80° C., the adhesive for mounting an electronic component starts curing before melting of solder, and therefore, the resin (adhesive) tends to be trapped in the soldered part during the mounting, lowering bonding reliability. If the 10-hr half-life temperature is 140° C. or higher, solder flow may occur. The 10-hr half-life temperature is more preferably 90° C. or higher but lower than 130° C.

Examples of the peroxide include ketone peroxide, peroxyketal, hydroperoxide, dialkyl peroxide, diacyl peroxide, peroxy ester, and peroxydicarbonate.

Among the peroxides, examples of commercial organic peroxides include PEROYL 355 (10-hr half-life temperature: 59.4° C.), PEROYL L (10-hr half-life temperature: 61.6° C.), PEROCTA O (10-hr half-life temperature: 65.3° C.), PEROYL SA (10-hr half-life temperature: 65.9° C.), PERHEXA 250 (10-hr half-life temperature: 66.2° C.), PERHEXYL O (10-hr half-life temperature: 69.9° C.), NYPER PMB (10-hr half-life temperature: 70.6° C.), PERBUTYL O (10-hr half-life temperature: 72.1° C.), NYPER BMT (10-hr half-life temperature: 73.1° C.), NYPER BW (10-hr half-life temperature: 73.6° C.), PERHEXA MC (10-hr half-life temperature: 83.2° C.), PERHEXA TMH (10-hr half-life temperature: 86.7° C.), PERHEXA HC (10-hr half-life temperature: 87.1° C.), PERHEXA C (10-hr half-life temperature: 90.7° C.), PERTETRA A (10-hr half-life temperature: 94.7° C.), PERHEXYL I (10-hr half-life temperature: 95.0° C.), PERBUTYL MA (10-hr half-life temperature: 96.1° C.), PERBUTYL 355 (10-hr half-life temperature: 97.1° C.), PERBUTYL L (10-hr half-life temperature: 98.3° C.), PERBUTYL I (10-hr half-life temperature: 98.7° C.), PERBUTYL E (10-hr half-life temperature: 99.0° C.), PERHEXYL Z (10-hr half-life temperature: 99.4° C.), PERHEXA 25Z (10-hr half-life temperature: 99.7° C.), PERBUTYL A (10-hr half-life temperature: 101.9° C.), PERHEXA 22 (10-hr half-life temperature: 103.1° C.), PERBUTYL Z (10-hr half-life temperature: 104.3° C.), PERHEXA V (10-hr half-life temperature: 104.5° C.), PERBUTYL D (10-hr half-life temperature: 123.7° C.), PERCUMYL D (10-hr half-life temperature: 116.4° C.), and PERHEXYNE 25B (10-hr half-life temperature: 128.4° C.) (all produced by NOF Corporation).

These peroxides may be used alone, or in combination of two or more thereof.

The amount of the radical polymerization initiator is not particularly limited, and the lower limit thereof is preferably 0.5 parts by weight and the upper limit thereof is preferably 20 parts by weight for 100 parts by weight of the acrylic polymer having a (meth)acryloyl group in aside chain. When the amount is less than 0.5 parts by weight, solder flow may occur. The amount of more than 20 parts by weight does not further contribute to the curability of the adhesive for mounting an electronic component. The lower limit of the amount is more preferably 1 part by weight, and the upper limit thereof is more preferably 15 parts by weight.

The adhesive for mounting an electronic component of the present invention preferably further contains an epoxy resin and an epoxy curing agent. Containing these components, the adhesive for mounting an electronic component has higher bonding reliability and heat resistance, and better reflowing resistance.

The epoxy resin is not particularly limited, and preferably contains an epoxy compound that has an epoxy group and a (meth)acryloyl group in one molecule because it is taken into the reaction system of the acrylic polymer having a (meth)acryloyl group in a side chain and the tri- or higher functional (meth)acrylate compound. Any compound that has an epoxy group and a (meth)acryloyl group in one molecule herein is regarded to be the “epoxy resin.” Here, the number of (meth)acryloyl groups in one molecule is not particularly limited.

Examples of the epoxy compound that has an epoxy group and a (meth)acryloyl group in one molecule include compounds prepared by partially converting or modifying an epoxy group of a commonly used epoxy resin to a (meth)acrylic group. The commonly used epoxy resin is not particularly limited, and examples thereof include bisphenol A-type epoxy resins, bisphenol F-type epoxy resins, phenol novolac-type epoxy resins, cresol novolac-type epoxy resins, dicyclopentadiene-type epoxy resins and naphthalene-type epoxy resins. The epoxy compound that has an epoxy group and a (meth)acryloyl group in one molecule may be 4-hydroxybutyl acrylate glycidyl ether or the like. These epoxy compounds that have an epoxy group and a (meth)acryloyl group in one molecule may be used alone, or in combination of two or more thereof. Particularly preferred is a compound having a structure represented by the following formula (1).

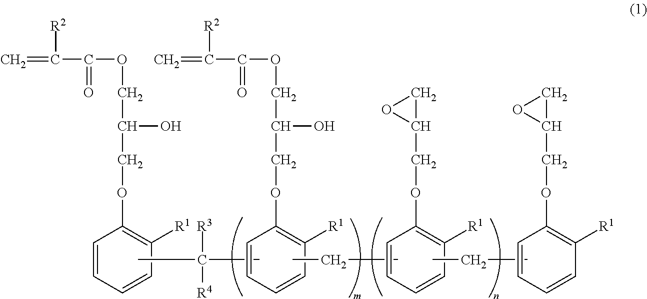

In the formula (1), R¹, R², R³, and R⁴ each represent a hydrogen atom or a methyl group and m and n each represent 0 or a positive integer. The m and n are not particularly limited as long as they each represent 0 or a positive integer, and preferably, “m+n” is within a range of 0 to 15.

The epoxy compound that has an epoxy group and a (meth)acryloyl group in one molecule may be used in combination with a common epoxy resin such as a bisphenol A-type epoxy resin, bisphenol F-type epoxy resin, phenol novolac-type epoxy resin, cresol novolac-type epoxy resin, dicyclopentadiene-type epoxy resin, or naphthalene-type epoxy resin.

The amount of the epoxy resin is not particularly limited, and the lower limit thereof is preferably 5 parts by weight and the upper limit thereof is preferably 300 parts by weight for 100 parts by weight of the acrylic polymer having a (meth)acryloyl group in a side chain. When the amount is less than 5 parts by weight, the bonding reliability or heat resistance of the adhesive for mounting an electronic component may be lowered. When the amount is more than 300 parts by weight, solder flow is likely to occur to possibly lower soldering properties. Moreover, voids are likely to be formed in the cooling step after the mounting. The lower limit of the amount is more preferably 10 parts by weight, and the upper limit thereof is more preferably 200 parts by weight.

The epoxy curing agent is not particularly limited, and a conventionally known epoxy curing agent may be appropriately selected in accordance with the epoxy resin. Examples thereof include acid anhydride curing agents, phenol curing agents, amine curing agents, latent curing agents such as dicyandiamide, cationic catalyst-type curing agents, imidazole curing agents, and tertiary amine curing accelerators. These epoxy curing agents may be used alone, or in combination of two or more thereof. In particular, preferred are acid anhydride curing agents because the curing rate and physical properties of the cured material can be easily adjusted. Also preferred are imidazole curing agents because the reaction system can be easily controlled for adjusting the curing rate and physical properties of the cured material.

Examples of commercial acid anhydride curing agents include YH-306, YH-307 (both produced by Mitsubishi Chemical Corporation, liquid at normal temperature (25° C.)), and YH-309 (produced by Mitsubishi Chemical Corporation, solid at normal temperature (25° C.)). These acid anhydride curing agents may be used alone, or in combination of two or more thereof.

The imidazole curing agents are not particularly limited, and examples thereof include Fujicure 7000, Fujicure 7001, Fujicure 7002 (all produced by T&K TOKA Corporation, liquid at normal temperature (25° C.)), 1-cyanoethyl-2-phenylimidazole in which 1-position of imidazole is protected with a cyanoethyl group, imidazole curing agents in which basicity is protected by isocyanuric acid (product name “2MA-OK”, produced by Shikoku Chemicals Corporation, solid at normal temperature (25° C.)), 2MZ, 2MZ-P, 2PZ, 2PZ-PW, 2P4MZ, C11Z-CNS, 2PZ-CNS, 2PZCNS-PW, 2MZ-A, 2MZA-PW, C11Z-A, 2E4MZ-A, 2MAOK-PW, 2PZ-OK, 2MZ-OK, 2PHZ, 2PHZ-PW, 2P4MHZ, 2P4MHZ-PW, 2E4MZ.BIS, VT, VT-OK, MAVT, and MAVT-OK (all produced by Shikoku Chemicals Corporation). These imidazole curing agents may be used alone or in combination of two or more thereof.

The amount of the epoxy curing agent is not particularly limited. In the case of using an epoxy curing agent that reacts with an equimolar amount of epoxy groups, the lower limit of the amount of the epoxy curing agent is preferably 60 equivalents and the upper limit thereof is preferably 110 equivalents based on the total amount of the epoxy groups contained in the adhesive for mounting an electronic component. When the amount is less than 60 equivalents, the epoxy resin may not be sufficiently cured. The amount of more than 110 equivalents does not further contribute to the curability of the adhesive for mounting an electronic component. On the contrary, such an excessive amount of curing agent is volatilized to possibly cause formation of voids. The lower limit of the amount is more preferably 70 equivalents and the upper limit thereof is more preferably 100 equivalents.

The adhesive for mounting an electronic component of the present invention preferably further contains an inorganic filler. Containing an inorganic filler, the adhesive for mounting an electronic component provides a cured product with higher mechanical strength and higher heat resistance. In addition, the cured product has a lower linear expansion coefficient to have higher bonding reliability.

The inorganic filler is not particularly limited, and examples thereof include silica, alumina, aluminum nitride, boron nitride, silicon nitride, silicon carbide, magnesium oxide, and zinc oxide. Preferred among these is spherical silica because of its excellent fluidity. More preferred is spherical silica surface-treated with a methylsilane coupling agent, a phenylsilane coupling agent, a vinylsilane coupling agent, a (meth)acrylsilane coupling agent, or the like. The use of surface-treated spherical silica improves the film forming properties of the adhesive for mounting an electronic component.

The average particle size of the inorganic filler is not particularly limited, and is preferably about 0.01 to 1 μm in terms of the transparency, fluidity, and bonding reliability of the adhesive for mounting an electronic component.

Each of the inorganic fillers may be used alone, or plural kinds of the inorganic fillers may be used in combination.

The amount of the inorganic filler is not particularly limited. The lower limit thereof is 10% by weight and the upper limit thereof is 70% by weight in the adhesive for mounting an electronic component. If the amount is less than 10% by weight, the adhesive for mounting an electronic component may give a cured product with lower strength or lower bonding reliability. If the amount is more than 70% by weight, the film forming properties of the adhesive for mounting an electronic component maybe lowered. The lower limit of the amount is more preferably 20% by weight, and the upper limit thereof is more preferably 60% by weight.

The adhesive for mounting an electronic component of the present invention preferably further contains a silane coupling agent having a (meth)acrylic group. Containing a silane coupling agent having a (meth)acrylic group, the adhesive for mounting an electronic component has higher adhesion to a semiconductor wafer or chip made of silicon or the like, so that detachment or a package crack does not occur at the adhesion interface with the semiconductor wafer or chip even under severe wet heat conditions such as reflowing, resulting in high bonding reliability.

Examples of the silane coupling agent having a (meth)acrylic group include 3-methacryloxypropyl methyldimethoxysilane, 3-methacryloxypropyl trimethoxysilane, 3-methacryloxypropyl methyldiethoxysilane, 3-methacryloxypropyl triethoxysilane, and 3-acryloxypropyl trimethoxysilane. These silane coupling agents having a (meth)acrylic group may be used alone, or in combination of two or more thereof.

The amount of the silane coupling agent having a (meth)acrylic group is not particularly limited. The lower limit thereof is preferably 0.05% by weight and the upper limit thereof is preferably 5% by weight in the adhesive for mounting an electronic component. When the amount is less than 0.05% by weight, detachment or a package crack may occur at the adhesion interface between the semiconductor wafer or chip and the adhesive for mounting an electronic component under severe wet heat conditions such as reflowing. The amount of more than 5% by weight does not further contribute to the improvement of the adhesion and wet-heat resistance of the adhesive for mounting an electronic component. The lower limit of the amount is more preferably 0.1% by weight, and the upper limit thereof is more preferably 3% by weight.

The adhesive for mounting an electronic component of the present invention may further contain other additives such as a diluent, a thixotropy-imparting agent, a solvent, an inorganic ion exchanger, a bleed inhibitor, a titanate coupling agent, an adhesion imparting agent (e.g., a tackifier), and a stress reliever (e.g., rubber particles).

A method for producing the adhesive for mounting an electronic component of the present invention is not particularly limited. In an exemplary method, the acrylic polymer having a (meth)acryloyl group in a side chain, the tri- or higher functional (meth)acrylate compound, and the radical polymerization initiator are mixed together optionally with other components each in a predetermined amount.

The mixing method is not particularly limited, and for example, a homogenizing disperser, a universal mixer, a Banbury mixer, a kneader or the like is used.

The application of the adhesive for mounting an electronic component of the present invention is not particularly limited. If the adhesive for mounting an electronic component of the present invention is used for flip chip mounting, sufficient soldering can be achieved while solder flow is prevented in a short mounting time. Moreover, voids can be suppressed and reflowing resistance can be improved.

In particular, preferably, the adhesive for mounting an electronic component of the present invention is formed into an adhesive layer of an adhesive film for mounting a flip chip. The adhesive film is attached to a substrate or a semiconductor chip in advance, so that bonding of electrodes and curing of the adhesive can be concurrently performed by heating for mounting of a semiconductor chip.

The present invention also encompasses an adhesive film for mounting a flip chip which has an adhesive layer made of the adhesive for mounting an electronic component of the present invention. The adhesive film for mounting a flip chip of the present invention may have any thickness, and the lower limit thereof is preferably 5 μm, whereas the upper limit thereof is preferably 60 μm. The lower limit is more preferably 10 μm, and the upper limit thereof is more preferably 50 μm.

The adhesive film for mounting a flip chip of the present invention may be produced by any method. In an exemplary method, the acrylic polymer having a (meth)acryloyl group in a side chain, the tri- or higher functional (meth)acrylate compound, and the radical polymerization initiator are mixed together optionally with other components and a solvent each in a predetermined amount, and the resulting adhesive solution is applied to a mold release film and then dried to give a film.

### Advantageous Effects of Invention

The present invention can provide an adhesive for mounting an electronic component. The adhesive enables sufficient soldering while preventing solder flow in a short mounting time, suppresses voids, and is excellent in reflowing resistance. The present invention also can provide an adhesive film for mounting a flip chip. The adhesive film contains the adhesive for mounting an electronic component.

### DESCRIPTION OF EMBODIMENTS

The present invention is more specifically described in the following with reference to, but not limited to, examples.

### Examples 1 to 14, Comparative Examples 1 to 4

### (1) Preparation of Adhesive Film

Materials shown in Table 1 were used (in Table 1, MMA represents methyl methacrylate, BA represents butyl acrylate, and HEMA represents hydroxyethyl methacrylate). In accordance with the compounding composition shown in Table 2 or 3, materials were added to methyl ethyl ketone (MEK) as a solvent and stirred with a homogenizing disperser to give an adhesive solution. The obtained adhesive solution was applied to a mold release PET film using an applicator to give a thickness after drying of 30 μm, and then dried to give an adhesive film. The surface of the obtained adhesive layer was protected with a mold release PET film (protective film) before use.

### (2) Production of Semiconductor Package

A wafer in which bumps with a solder top portion are formed in peripheral arrangement at a pitch of 50 μm (WALTS-TEG MB50-0101JY, solder melting point of 235° C., Walts Co., Ltd.) was prepared. The protective film on one surface of the adhesive film was peeled. The adhesive film was then attached to the wafer surface having bumps formed thereon using a vacuum laminator (ATM-812M, available from Takatori Corporation) at a stage temperature of 80° C. and a vacuum degree of 100 Pa.

The mold release PET film on the other surface of the adhesive film was peeled, and a protective tape for grinding (ELEP HOLDER BT3100P, Nitto Denko Corporation) was laminated on the exposed adhesive face. Then, the rear face of the wafer was ground with a grinder (DFG8560, Disco Corporation) to a thickness of 100 μm. A dicing tape was attached to the ground face of the wafer, and the protective tape for grinding was peeled. The wafer was then diced using a dicing machine (DFD651, Disco Corporation) at a feed speed of 20 mm/sec to give a semiconductor chip (7.6 mm×7.6 mm) with an adhesive layer that has a thickness of 30 μm.

A substrate having a Ni/Au electrode (WALTS-KIT MB50-0101JY, Walts Co., Ltd.) was prepared. The obtained semiconductor chip with an adhesive layer was heat-bonded to the substrate by heating at a temperature of 120° C. (contact temperature) that was raised to 280° C. in two seconds and pressuring them at 0.8 MPa at 280° C. using a flip chip bonder (FC-3000, Toray Engineering Co., Ltd.) under the condition of a bonding stage temperature of 100° C. Then, the resulting product was held in an oven at 190° C. under normal pressure for 30 minutes so that the adhesive layer was completely cured. Thus, a semiconductor package was prepared.

### <Evaluation>

The semiconductor packages obtained in the examples and comparative examples were subjected to the following evaluations. Tables 2 and 3 show the results.

### (1) Solder Flow

The soldered part of the semiconductor package was observed using an X-ray transmission device (MF100C, Hitachi Engineering and Services Co., Ltd.) to determine the presence or absence of solder flow. The package in which solder is present only in the soldered part was regarded to be a good quality product (∘), whereas the package in which solder flows during bonding to be insularly present outside the soldered part was regarded to be a poor quality product (x).

### (2) Soldering Properties

The cross section of the semiconductor package was polished using a polisher, and the bonding state at the soldered part was observed using a microscope. When the bonding state is favorable and the resin (adhesive) is not trapped between the upper and lower electrodes or outflow of solder due to solder flow was not present, such a semiconductor package was regarded to be a good quality product (∘). When the bonding state is comparatively favorable and no outflow of solder due to solder flow was present though the resin (adhesive) is slightly trapped between the upper and lower electrodes, such a semiconductor package was regarded to be an average quality product (Δ). When the resin (adhesive) is trapped between the upper and lower electrodes or outflow of solder due to solder flow was found and the upper and lower electrodes were not bonded to each other, such a semiconductor package was regarded to be a poor quality product (x).

### (3) Voids

The semiconductor package was observed using an ultrasonic inspection imaging device (C-SAM D9500, Nippon BARNES Company Ltd.) to determine the presence or absence of voids. The semiconductor package regarded to be a good quality product (∘) had an area of voids of less than 0.5% relative to the adhesion area of the semiconductor chip. The semiconductor package regarded to be an average quality product (Δ) had an area of voids of 0.5% or more but less than 1% relative to the adhesion area of the semiconductor chip. The semiconductor package regarded to be a poor quality product (x) had an area of voids of 1% or more relative to the adhesion area of the semiconductor chip. In determination of the quality of products, five samples of the semiconductor package were observed and the quality of the sample with a smallest area of voids relative to the adhesion area of the semiconductor chip was used.

### (4) Reflowing Resistance Test

The semiconductor package was left at 85° C. and 60 RH % for 168 hours to absorb moisture, and then passed through a solder reflow furnace (preheating: 150° C.×100 seconds, reflowing [maximum temperature of 260° C.]) four times. Twenty samples of the semiconductor package underwent the test and the number of the samples in which the semiconductor chip was detached from the substrate was determined. When the number of samples in which detachment occurred was 0 out of 20, such a semiconductor package was regarded to be good (∘). When the number of samples in which detachment occurred was 1 to 3 out of 20, such a semiconductor package was regarded to be fair (Δ). When the number of samples in which detachment occurred was 4 to 20 out of 20, such a semiconductor package was regarded to be poor (x).

TABLE 1

| | Trade name | Maker | Structure |
|---|---|---|---|
| Acrylic polymer | Polymer A | — | Ppolymer obtained by reacting MMA/BA/HEMA copolymer with MOI, |
| | | | Double bond equivalent of 0.6 meq/g, Mw of 400000 |
| | Polymer B | — | Polymer obtained by reacting MMA/BA/HEMA copolymer with MOI, |
| | | | Double bond equivalent of 0.9 meq/g, Mw of 140000 |
| | Polymer C | — | Polymer obtained by reacting MMA/BA/HEMA copolymer with MOI, |
| | | | Double bond equivalent of 1.2 meq/g, Mw of 300000 |
| | Polymer D | — | Polymer obtained by reacting MMA/BA/HEMA copolymer with MOI, |
| | | | Double bond equivalent of 1.5 meq/g, Mw of 200000 |
| | Polymer E | — | Polymer obtained by reacting HEMA homopolymer with MOI, Double |
| | | | bond equivalent of 3.5 meq/g, Mw of 180000 |
| | Polymer F | — | Polymer obtained by reacting MMA/BA/HEMA copolymer with MOI, |
| | | | Double bond equivalent of 1.0 meq/g, Mw of 250000 |
| Polyfunctional | A-HD-N | Shin-Nakamura | 1,6-Hexanediol diacrylate |
| (meth)acrylate | | Chemical Co., Ltd. | |
| compound | Epoxy ester | Kyoeisha Chemical | Acrylic acid adduct of bisphenol A diglycidyl ether |
| | 3000A | Co., Ltd. | |
| | A-9300 | Shin-Nakamura | Ethoxylated isocyanuric acid triacrylate |
| | | Chemical Co., Ltd. | |
| | Light Acrylate | Kyoeisha Chemical | Trimethylolpropane triacrylate |
| | TMP-A | Co., Ltd. | |
| | Light Acrylate | Kyoeisha Chemical | Pentaerythritol tetraacrylate |
| | PE-4A | Co., Ltd. | |
| | A-DPH | Shin-Nakamura | Dipentaerythritol hexaacrylate |
| | | Chemical Co., Ltd. | |
| Epoxy resin | NK Oligo | Shin-Nakamura | Cresol novolac epoxy acrylate (In Formula (1), R¹ represents methyl group, |
| | EA-7310N | Chemical Co., Ltd. | R², R³, R⁴ each represent hydrogen atom, m + n is not more than 6) |
| Radical polymerization | PERHEXA TMH | NOF Corporation | 1,1,-Di(t-hexylperoxy)-3,3,5-trimethylcyclohexane (10-hr |
| initiator | | | half-life temperature of 86.7° C.) |
| | PERCUMYL D | NOF Corporation | Dicumyl peroxide (10-hr half-life temperature of 116.4° C.) |
| | PERBUTYL 355 | NOF Corporation | t-Butylperoxy-3,5,5-trimethyl hexanoate (10-hr half-life |
| | | | temperature of 97.1° C.) |
| | PERBUTYL D | NOF Corporation | Di-t-butylperoxide (10-hr half-life temperature of 123.7° C.) |
| Epoxy curing agent | Fujicure 7000 | T&K TOKA Corporation | Liquid imidazole |
| Inorganic filler | SSP-01PT | Tokuyama Corporation | Surface-treated spherical silica filler (surface treatment |
| | | | with phenyl silane coupling agent, average particle size of 0.1 μm) |
| Silane coupling agent | KBM-5103 | Shin-Etsu Chemical | 3-Acryloxypropyl trimethoxysilane |
| | | Co., Ltd. | |

MOI: 2-Methacryloyloxyethyl isocyanate (Showa Denko K.K., Karenz MOI)

TABLE 2

| | | | | Exam- | Exam- | Exam- | Exam- | Exam- | Exam- | Exam- |
|---|---|---|---|---|---|---|---|---|---|---|
| | | | | ple 1 | ple 2 | ple 3 | ple 4 | ple 5 | ple 6 | ple 7 |
| Compounding | Acrylic polymer | Polymer A | 0.6 meq/g | — | — | — | — | — | — | — |
| composition | | Polymer B | 0.9 meq/g | — | — | — | — | — | — | — |
| (parts by | | Polymer C | 1.2 meq/g | — | — | 1 | — | — | — | — |
| weight) | | Polymer D | 1.5 meq/g | 1 | 1 | — | 2 | — | 1.6 | 0.6 |
| | | Polymer E | 3.5 meq/g | — | — | — | — | 1 | — | — |
| | | Polymer F | 1.0 meq/g | — | — | — | — | — | — | — |
| | Polyfunctional | A-HD-N(HDDA) | Bifunctional | — | — | — | — | — | — | — |
| | (meth)acrylate | Epoxy ester | Bifunctional | — | — | — | — | — | — | — |
| | compound | 3000A | | | | | | | | |
| | | A-9300 | Trifunctional | 1 | — | 1 | 1 | 1 | 0.4 | 1.4 |
| | | Light acrylate | Trifunctional | — | — | — | — | — | — | — |
| | | TMP-A | | | | | | | | |
| | | Light acrylate | Tetrafunctional | — | — | — | — | — | — | — |
| | | PE-4A | | | | | | | | |
| | | A-DPH(DPHA) | Hexafunctional | — | 1 | — | — | — | 1.4 | — |
| | Epoxy resin | NK Oligo | | 1 | 1 | 1 | — | 1 | 1 | 1 |
| | | EA-7310N | | | | | | | | |
| | Radical | PERHEXA TMH | | — | — | — | — | — | — | — |
| | polymerization | PERCUMYL D | | 0.05 | 0.05 | 0.05 | 0.05 | 0.05 | 0.05 | 0.05 |
| | initiator | PERBUTYL 355 | | — | — | — | — | — | — | — |
| | | PERBUTYL D | | — | — | — | — | — | — | — |
| | Epoxy curing | Fijicure 7000 | | 0.1 | 0.1 | 0.1 | — | 0.1 | 0.1 | 0.1 |
| | agent | | | | | | | | | |
| | Inorganic filler | SSP-01PT | | 3 | 3 | 3 | 3 | 3 | 3 | 3 |
| | Silane coupling | KBM-5103 | | 0.02 | 0.02 | 0.02 | 0.02 | 0.02 | 0.02 | 0.02 |
| | agent | | | | | | | | | |
| Evaluation | Solder flow | | | ◯ | ◯ | ◯ | ◯ | ◯ | ◯ | ◯ |
| | Soldering properties | | | ◯ | ◯ | ◯ | ◯ | ◯ | ◯ | ◯ |
| | Void | | | ◯ | ◯ | ◯ | ◯ | ◯ | ◯ | ◯ |
| | Reflowing resistance test | | | ◯ | ◯ | ◯ | Δ | ◯ | ◯ | ◯ |
| | | | | Exam- | Exam- | Exam- | Exam- | Exam- | Exam- | Exam- |
| | | | | ple 8 | ple 9 | ple 10 | ple 11 | ple 12 | ple 13 | ple 14 |
| Compounding | Acrylic polymer | Polymer A | 0.6 meq/g | — | — | — | — | — | — | — |
| composition | | Polymer B | 0.9 meq/g | — | — | — | — | — | — | — |
| (parts by | | Polymer C | 1.2 meq/g | — | — | — | — | 1 | 1 | 1 |
| weight) | | Polymer D | 1.5 meq/g | 1.4 | 1 | 1 | — | — | — | — |
| | | Polymer E | 3.5 meq/g | — | — | — | — | — | — | — |
| | | Polymer F | 1.0 meq/g | — | — | — | 1 | — | — | — |
| | Polyfunctional | A-HD-N(HDDA) | Bifunctional | — | — | — | — | — | — | — |
| | (meth)acrylate | Epoxy ester | Bifunctional | — | — | — | — | — | — | — |
| | compound | 3000A | | | | | | | | |
| | | A-9300 | Trifunctional | 1.4 | 1 | 1 | 1 | — | — | 1 |
| | | Light acrylate | Trifunctional | — | — | — | — | 1 | — | — |
| | | TMP-A | | | | | | | | |
| | | Light acrylate | Tetrafunctional | — | — | — | — | — | 1 | — |
| | | PE-4A | | | | | | | | |
| | | A-DPH(DPHA) | Hexafunctional | — | — | — | — | — | — | — |
| | Epoxy resin | NK Oligo | | 0.2 | 1 | 1 | 1 | 1 | 1 | 1 |
| | | EA-7310N | | | | | | | | |
| | Radical | PERHEXA TMH | | — | — | — | — | — | — | 0.05 |
| | polymerization | PERCUMYL D | | 0.05 | — | — | 0.05 | 0.05 | 0.05 | — |
| | initiator | PERBUTYL 355 | | — | 0.05 | — | — | — | — | — |
| | | PERBUTYL D | | — | — | 0.05 | — | — | — | — |
| | Epoxy curing | Fijicure 7000 | | — | 0.1 | 0.1 | 0.1 | 0.1 | 0.1 | 0.1 |
| | agent | | | | | | | | | |
| | Inorganic filler | SSP-01PT | | 3 | 3 | 3 | 3 | 3 | 3 | 3 |
| | Silane coupling | KBM-5103 | | 0.02 | 0.02 | 0.02 | 0.02 | 0.02 | 0.02 | 0.02 |
| | agent | | | | | | | | | |

| | | | | | | | | |
|---|---|---|---|---|---|---|---|---|
| Evaluation | Solder flow | ◯ | ◯ | ◯ | ◯ | ◯ | ◯ | ◯ |
| | Soldering properties | ◯ | ◯ | ◯ | Δ | ◯ | ◯ | Δ |
| | Void | ◯ | ◯ | ◯ | Δ | ◯ | ◯ | ◯ |
| | Reflowing resistance test | Δ | ◯ | ◯ | ◯ | Δ | Δ | ◯ |

TABLE 3

| | | | | Comparative | Comparative | Comparative | Comparative |
|---|---|---|---|---|---|---|---|
| | | | | Example 1 | Example 2 | Example 3 | Example 4 |
| Compounding | Acrylic polymer | Polymer A | 0.6 meq/g | 1 | — | — | — |
| composition | | Polymer B | 0.9 meq/g | — | 1 | — | — |
| (parts by | | Polymer C | 1.2 meq/g | — | — | 1 | 1 |
| weight) | | Polymer D | 1.5 meq/g | — | — | — | — |
| | | Polymer E | 3.5 meq/g | — | — | — | — |
| | | Polymer F | 1.0 meq/g | — | — | — | — |
| | Polyfunctional | A-HD-N(HDDA) | Bifunctional | — | — | 1 | — |
| | (meth)acrylate | Epoxy ester | Bifunctional | — | — | — | 1 |
| | composition | 3000A | | | | | |
| | | A-9300 | Trifunctional | 1 | 1 | — | — |
| | | Light acrylate | Trifunctional | — | — | — | — |
| | | TMP-A | | | | | |
| | | Light acrylate | Tetrafunctional | — | — | — | — |
| | | PE-4A | | | | | |
| | | A-DPH(DPHA) | Hexafunctional | — | — | — | — |
| | Epoxy resin | NK Oligo | | 1 | 1 | 1 | 1 |
| | | EA-7310N | | | | | |
| | Radical polymerization | PERHEXA TMH | | — | — | — | — |
| | initiator | PERCUMYL D | | 0.05 | 0.05 | 0.05 | 0.05 |
| | | PERBUTYL 355 | | — | — | — | — |
| | | PERBUTYL D | | — | — | — | — |
| | Epoxy curing agent | Fujicure 7000 | | 0.1 | 0.1 | 0.1 | 0.1 |
| | Inorganic filler | SSP-01PT | | 3 | 3 | 3 | 3 |
| | Silane coupling agent | KBM-5103 | | 0.02 | 0.02 | 0.02 | 0.02 |

| | | | | | |
|---|---|---|---|---|---|
| Evaluation | Solder flow | x | x | x | x |
| | Soldering properties | x | x | x | x |
| | Void | x | x | x | x |
| | Reflowing resistance test | x | x | x | x |

### INDUSTRIAL APPLICABILITY

The present invention can provide an adhesive for mounting an electronic component. The adhesive enables sufficient soldering while preventing solder flow in a short mounting time, suppresses voids, and is excellent in reflowing resistance. The present invention can also provide an adhesive film for mounting a flip chip. The adhesive film contains the adhesive for mounting an electronic component.

1. An adhesive for mounting an electronic component comprising:
an acrylic polymer having a (meth)acryloyl group in a side chain and having a double bond equivalent of 1 to 5 meq/g;
a tri- or higher functional (meth)acrylate compound; and
a radical polymerization initiator.

2. The adhesive for mounting an electronic component according to claim 1, wherein the radical polymerization initiator is a heat radical polymerization initiator.

3. The adhesive for mounting an electronic component according to claim 1, further comprising an epoxy resin and an epoxy curing agent.

4. The adhesive for mounting an electronic component according to claim 3,
wherein the epoxy resin contains an epoxy compound having an epoxy group and a (meth)acryloyl group in one molecule.

5. The adhesive for mounting an electronic component according to claim 1, further comprising an inorganic filler.

6. The adhesive for mounting an electronic component according to claim 1, further comprising a silane coupling agent having a (meth)acrylic group.

7. The adhesive for mounting an electronic component according to claim 1,
wherein the acrylic polymer having a (meth)acryloyl group in a side chain and having a double bond equivalent of 1 to 5 meq/g has a (meth)acryloyl group only in the side chain.

8. An adhesive film for mounting a flip chip comprising an adhesive layer formed from the adhesive for mounting an electronic component according to claim 1.
